(19) United States
(12) Patent Application Publication
(10) Pub. No.: US 2026/0332097 A1
(43) Pub. Date: Oct. 22, 2026

(54) INDUCTOR-CAPACITOR COMPLEMENTARY VOLTAGE-CONTROLLED OSCILLATOR WITH SHARED COMMON-MODE FILTER

(71) Applicant: Apple Inc., Cupertino, CA (US)

(72) Inventor: Omar E Elaasar, San Diego, CA (US)

(21) Appl. No.: 19/181,008

(22) Filed: Apr. 16, 2025

(51) Int. Cl. H03B 5/12

(52) U.S. Cl. CPC H03B 5/1212; H03B 2200/0088

(57) ABSTRACT

This disclosure is directed to an inductor-capacitor voltage-controlled oscillator (VCO) with increased bandwidth and/or reduced common-mode noise compared to other VCOs. The VCO may include a common-mode filter disposed away from (e.g., not directly coupled to) a decoupling network to decrease undesired resonant frequency shifts of the common-mode filter. The separated common-mode filter and the decoupling network may reduce the parasitic capacitances and/or inductances and/or variations of the capacitance and inductance at different nodes of the VCO over an expanded oscillation frequency bandwidth. Accordingly, the common-mode filter may have decreased undesired resonant frequency shifts over the expanded oscillation frequency bandwidth and, therefore, the VCO may have the expanded oscillation frequency bandwidth.

### BACKGROUND

The present disclosure relates generally to wireless communication, and more specifically to voltage-controlled oscillators of transmitter and/or receiver circuits.

In some applications, a voltage-controlled oscillator (VCO) may include current source circuitry, resonator circuitry, and a common-mode filter. The current source circuitry may generate a direct current (DC) signal based on receiving a bias voltage. The resonator circuitry may receive the DC signal from the current source circuitry and generate a VCO output signal based on the DC signal. For example, the resonator circuitry may generate the output signal with an oscillation frequency and voltage amplitude based on an inductive and capacitive value of components of the resonator circuitry and an electrical current value of the DC signal. In some cases, the common-mode filter may suppress at least a portion of one or more undesired noise signals of the output signal. However, undesired variations in electrical current or voltage at different nodes of the VCO may undesirably reduce suppression of the undesired noise signals by the common-mode filter.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, an electronic device may include a voltage-controlled oscillator including a first decoupling inductor, a first terminal of the first decoupling inductor coupled to a power source terminal, a first inductor-capacitor tank circuit coupled to a second terminal of the first decoupling inductor, a first current source circuit coupled to the first inductor-capacitor tank circuit, a differential capacitor, a first terminal of the differential capacitor coupled to the first current source circuit, a differential inductor, a first terminal of the differential inductor coupled to the first current source circuit, a second current source circuit coupled to a second terminal of the differential capacitor and a second terminal of the differential inductor, a second inductor-capacitor tank circuit coupled to the second current source circuit, and a second decoupling inductor coupled to the second inductor-capacitor tank circuit and a ground terminal.

In another embodiment, a transceiver may include a voltage-controlled oscillator and a mixer. The voltage-controlled oscillator may include a first current source circuit, a differential capacitor, a first terminal of the differential capacitor coupled to the first current source circuit, a differential inductor, a first terminal of the differential inductor coupled to the first current source circuit, and a second current source circuit coupled to a second terminal of the differential capacitor and a second terminal of the differential inductor, where the voltage-controlled oscillator may generate an output signal. The mixer may be coupled to the voltage-controlled oscillator and may generate a combined signal based on the output signal.

In yet another embodiment, a voltage-controlled oscillator may include a first current source circuit, a differential capacitor, a first terminal of the differential capacitor directly coupled to the first current source circuit, a differential inductor, a first terminal of the differential inductor directly coupled to the first current source circuit, and a second current source circuit directly coupled to a second terminal of the differential capacitor and a second terminal of the differential inductor.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a block diagram of components of a voltage-controlled oscillator (VCO) of the transmitter of FIG. 3 and/or the receiver of FIG. 4, according to embodiments of the present disclosure;

FIG. 6 is a schematic diagram of the VCO of FIG. 5 including a differential capacitor and a differential inductor with a common-mode filter of the VCO, according to embodiments of the present disclosure;

FIG. 7 is a schematic diagram of the VCO of FIG. 6 including single-ended capacitors with the common-mode filter, according to embodiments of the present disclosure;

FIG. 8 is a schematic diagram of the VCO of FIG. 7 including an impedance component with the common-mode filter, according to embodiments of the present disclosure; and

FIG. 9 is a layout of the VCO of FIGS. 5-8, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to an inductor-capacitor complementary voltage-controlled oscillator, hereinafter referred to as a VCO, with reduced common-mode noise compared to other VCOs that do not include the disclosed embodiments. In particular, the VCO may generate an output signal (e.g., a differential output signal) having an oscillation frequency and reduced common-mode noises compared to other VCOs. The VCO may include a common-mode filter and a decoupling network. The common-mode filter may include one or more capacitors and inductors having a resonant frequency corresponding to frequencies of the common-mode noises. As such, the common-mode filter may reduce (e.g., suppress) the undesired common-mode noises of the output signal.

An increase in the oscillation frequency of the output signal may correspond to a decrease in a value of the capacitors and/or inductors of the common-mode filter. In some cases, the increase in the oscillation frequency of the output signal may reduce capacitance and inductance values of the common-mode filter compared to that of the decoupling network. If not accounted for, in the reduced capacitance and inductance values of the common-mode filter may cause unpredictable, increased, and/or differing undesired parasitic capacitances and/or inductances at different nodes of the VCO. The undesired parasitic capacitances and/or inductances may undesirably shift the resonant frequency of the common-mode filter and increase (e.g., reduce suppression of) the common-mode noise.

In the embodiments disclosed herein, the VCO may reduce undesired resonant frequency shifts of the common-mode filter by having the common-mode filter disposed away from the decoupling network. In particular, the VCO may have the common-mode filter coupled directly to (e.g., coupled in-between) a first portion (e.g., a first cell) and a second portion (e.g., a second cell) of the VCO. The decoupling network may be coupled directly to (e.g., coupled in-between) the first portion and a power source terminal and coupled directly to (e.g., coupled in-between) the second portion of the VCO and a ground terminal. As such, the parasitic capacitances and/or inductances of the common-mode filter may have reduced dependency on that of the decoupling network.

The VCO may include the common-mode filter separated from the decoupling network to reduce at least a portion of adverse effects of having an expanded difference and/or gap in capacitance and inductance values of the common-mode filter and the decoupling network. For example, the parasitic capacitances and/or inductances of the common-mode filter and/or the decoupling network may be reduced. In some cases, the parasitic capacitances and/or inductances and/or variations of the capacitance and inductance at different nodes of the VCO may be reduced over an expanded oscillation frequency bandwidth. Accordingly, the common-mode filter may have reduced resonant frequency shifts over the expanded oscillation frequency bandwidth and, therefore, the VCO may have the expanded oscillation frequency bandwidth.

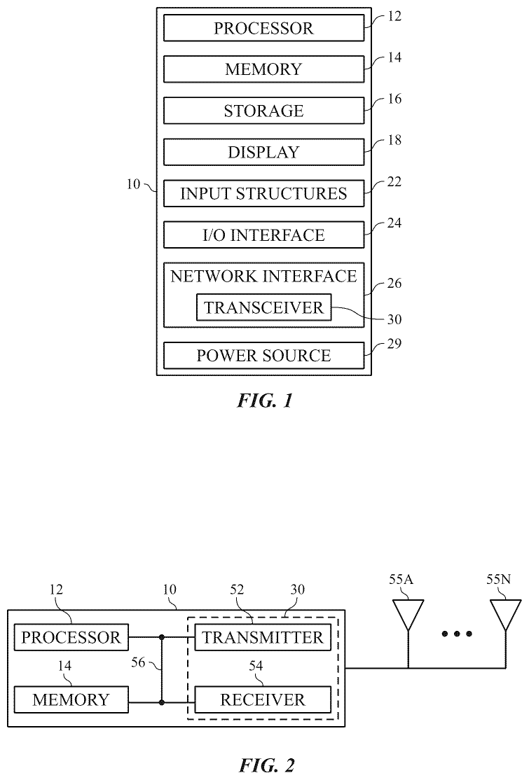

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH network, a local area network (LAN) or wireless local area network (WLAN), such as a network employing one of the IEEE 802.11x family of protocols (e.g., WI-FI), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX), mobile broadband Wireless networks (mobile WIMAX), asynchronous digital subscriber lines (e.g., ADSL, VDSL), digital video broadcasting-terrestrial (DVB-T) network and its extension DVB Handheld (DVB-H) network, ultra-wideband (UWB) network, alternating current (AC) power lines, and so forth.

As illustrated, the network interface 26 may include a transceiver or modem 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter or wireless transmission circuitry 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

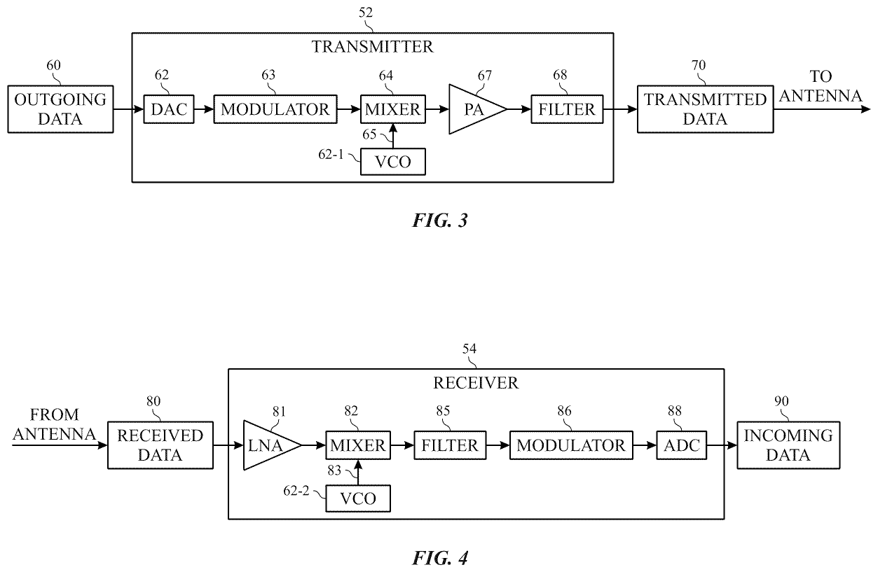

FIG. 3 is a schematic diagram of the transmitter 52 (e.g., transmit circuitry, the wireless transmission circuitry), according to embodiments of the present disclosure. As illustrated, the transmitter 52 may receive outgoing data 60 in the form of a digital signal to be transmitted via the one or more antennas 55. A digital-to-analog converter 62 of the transmitter 52 may convert the digital signal to an analog signal.

A modulator 63 may combine the converted analog signal with a carrier signal to generate a radio wave. A mixer 64 may combine the carrier signal with a local oscillator signal 65 to generate a radio frequency signal (e.g., a combined signal). The VCO 66-1 (e.g., a local oscillator) may generate the local oscillator signal 65 having an oscillation frequency (e.g., a carrier frequency). In additional or alternative embodiments, the VCO 66-1 may generate the carrier signal having the carrier frequency (e.g., the oscillation frequency).

A power amplifier 67 receives the modulated signal from the mixer 64. The power amplifier 67 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

Although the transmitter 52 is shown to include a single VCO 66-1, it should be appreciated that the electronic device 10 and/or the transmitter 52 may include additional VCOs 66-1. In different embodiments, the additional VCOs 66-1 may perform different operations of the electronic device 10 and/or the transmitter 52, such as frequency synthesis applications and clock generation applications. Furthermore, the power amplifier 67 and/or the filter 68 may be referred to as part of a radio frequency front end (RFFE), and more specifically, a transmit front end of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include additional mixers and/or VCOs 66-1. As another example, the transmitter 52 may not include the filter 68 if the power amplifier 67 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier 81 may amplify the received analog signal to a suitable level for the receiver 54 to process. A mixer 82 may combine (e.g., mix) the amplified signal with a local oscillator signal 83 to generate an intermediate frequency signal or a baseband frequency signal (e.g., a combined signal). A VCO 66-2 (e.g., a second VCO, a local oscillator) may generate the local oscillator signal 83 with an oscillation frequency, such as an intermediate frequency or baseband frequency, for down conversion of a frequency of the incoming RF signal for processing.

A filter 85 (e.g., filter circuitry and/or software) may remove undesired noise from the received signal 80, such as cross-channel interference. The filter 85 may also remove additional signals received by the one or more antennas 55 that are at frequencies other than the desired signal. The filter 85 may include any suitable filter or filters to remove the undesired noise or signals from the received signal 80, such as a bandpass filter, a bandstop filter, a low pass filter, a high pass filter, and/or a decimation filter. The low noise amplifier 81 and/or the filter 85 may be referred to as part of the RFFE, and more specifically, a receiver front end of the electronic device 10.

A demodulator 86 may remove a radio frequency carrier signal and/or extract a demodulated signal (e.g., an envelope signal) from the filtered signal for processing. In some embodiments, the demodulator 86 may receive a signal indicating a frequency and phase of the received signal 80 and/or the intermediate frequency or baseband frequency from the VCO 66-2 to generate the remove a radio frequency carrier signal and/or extract a demodulated signal (e.g., an envelope signal) from the filtered signal for processing. An analog-to-digital converter 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include additional mixers and/or VCOs 66-2.

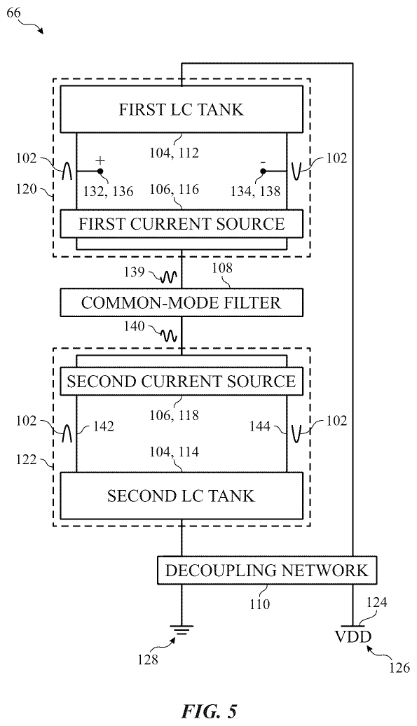

FIG. 5 is a block diagram of components of a VCO 66 of the transmitter 52 and/or the receiver 54 that may generate an output signal 102, according to embodiments of the present disclosure. For example, the VCOs 66-1 and 66-2 discussed above may be collectively referred to as the VCO 66. As discussed above, the transmitter 52 and/or the receiver 54 may include the VCO 66. The output signal 102 may include a differential output signal. In some embodiments, the output signal 102 may correspond to the local oscillator signal 65 and/or 83 discussed above. The VCO 66 may include inductor-capacitor (LC) tank circuitry 104 (e.g., differential resonator circuitry), current source circuitry 106 (e.g., voltage-controlled current source circuitry), a common-mode filter 108 (e.g., common-mode resonator, a tail filter), and a decoupling network 110. The LC tank circuitry 104 may include a first LC tank 112 and a second LC tank 114. The current source circuitry 106 may include a first current source 116 (e.g., a first voltage-controlled current source) and a second current source 118 (e.g., a second voltage-controlled current source).

The VCO 66 may include a first cell 120 and a second cell 122 each including a portion of (e.g., half of, near half of) the LC tank circuitry 104 and the current source circuitry 106. In particular, the first cell 120 may include the first LC tank 112 and the first current source 116. Moreover, the second cell 122 may include the second LC tank 114 and the second current source 118. The common-mode filter 108 may be disposed between and/or coupled to (e.g., coupled between) the first cell 120 and the second cell 122.

The first LC tank 112 may be coupled to a power source terminal 124 via (e.g., through) the decoupling network 110. The first LC tank 112 may receive a bias voltage 126 (e.g., VDD, a direct current (DC) signal) via the power source terminal 124. In some embodiments, the power source 29 discussed above may be coupled to the power source terminal 124. In some cases, the power source 29 may generate and/or output the bias voltage 126. Alternatively or additionally, the VCO 66 may receive the bias voltage 126 from any other viable circuit. Moreover, the first LC tank 112 may receive any other viable input signal in lieu or additional to the bias voltage 126.

The decoupling network 110 may include one or more capacitors and inductors. The decoupling network 110 may reduce voltage fluctuations of the bias voltage 126 and/or one or more noises and/or harmonics of the VCO 66 with respect to the power source terminal 124 and/or a ground terminal 128. For example, the decoupling network 110 may reduce one or more noises and/or harmonics of the VCO 66 with respect to other circuitry and/or components of the electronic device 10 including the VCO 66.

The first current source 116 may be differentially coupled to the first LC tank 112 via a first node 132 and a second node 134. In the depicted embodiment, the first node 132 may correspond to a positive output terminal 136 and the second node 134 may correspond to a negative output terminal 138 of the VCO 66. The first current source 116 may be coupled to the second current source 118 via the common-mode filter 108. As such, the first cell 120 may be coupled to the second cell 122 via (e.g., through) the common-mode filter 108. Moreover, the second current source 118 may be differentially coupled to the second LC tank 114 via (e.g., through) the decoupling network 110 via a third node 142 and a fourth node 144. In some embodiments, the third node 142 and the fourth node 144 may correspond to or have a second positive output terminal and a second negative output terminal of the VCO 66 (e.g., in lieu or in addition to the positive output terminal 136 and the negative output terminal 138). The second LC tank 114 may be coupled to the ground terminal 128 via the decoupling network 110. For example, the ground terminal 128 may have a ground voltage such as a virtual ground voltage, 0 volts, or near 0 volts. In some embodiments, the power source 29 discussed above may be coupled to the ground terminal 128.

The first current source 116 may receive the bias voltage 126 from the first LC tank 112. The common-mode filter 108 may provide a low impedance (e.g., a relative short circuit connection, approaching a short circuit impedance or resistance, near-zero or zero impedance or resistance, and so on) to the bias voltage 126. As such, the second current source 118 may receive the bias voltage 126 from the first cell 120 via the common-mode filter 108. Moreover, the first current source 116 and the second current source 118 may generate and/or provide a DC signal based on receiving the bias voltage 126. For example, the first current source 116 and the second current source 118 may each include a voltage-controlled current source to generate and/or output the DC signal (e.g., a desired electrical current). The DC signal may have an oscillation frequency of zero, near zero, approximately zero, relatively zero, and/or below a threshold frequency.

The LC tank circuitry 104, including the first LC tank 112 and the second LC tank 114, may generate the output signal 102 based on receiving the DC signal and/or the bias voltage 126. For example, the first LC tank 112 and the second LC tank 114 may have an oscillation frequency (e.g., a desired oscillation frequency) within a resonant frequency range. As such, the LC tank circuitry 104 may generate the output signal 102 with an oscillation frequency within the resonant frequency range. In some embodiments, the LC tank circuitry 104 may generate the output signal 102 with an oscillation frequency corresponding to a carrier signal having the carrier frequency for transmitting outgoing data 60 discussed above. In alternative or additional embodiments, the LC tank circuitry 104 may generate the output signal 102 with an oscillation frequency corresponding to an intermediate or baseband oscillating signal for down-conversion and processing of the received signal 80 discussed above.

In some cases, the VCO 66 may have undesired common-mode noises 139 on the first cell 120 and undesired common-mode noises 140 on the second cell 122. If not compensated for, the common-mode noises 139 and 140 may cause undesired voltage and/or frequency offsets around the output signal 102 causing undesired flicker and/or phase noise with the output signal 102. For example, the common-mode noises 139 and 140 may include an undesired flicker noise and/or phase noise, among other things, and/or may correspond to one or more undesired harmonics of the output signal, among other possibilities.

As mentioned above, the common-mode filter 108 may provide a low impedance (e.g., a relative short circuit connection) to the bias voltage 126. Moreover, the common-mode filter 108 may have a resonant frequency range associated with the undesired common-mode noises 139 and 140. As such, the common-mode filter 108 may reduce (e.g., suppress) the undesired common-mode noises 139 and 140 of the output signal 102 while providing a relatively short circuit path to the bias voltage 126, the DC signal, and the output signal 102. For example, the resonant frequency range may correspond to a frequency range associated with one or more harmonics (e.g., integer multiples) of the output signal 102 and/or the resonant frequency range of the LC tank circuitry 104.

The common-mode filter 108 may include one or more capacitors and inductors. Moreover, as mentioned above, the decoupling network 110 may include one or more capacitors and inductors. An increase in the oscillation frequency of the output signal 102 may disproportionately reduce one or more values of the capacitors and inductors of the common-mode filter 108 compared to that of the decoupling network 110. If not accounted for, reduced values of the capacitors and inductors of the common-mode filter 108 compared to that of the decoupling network 110 may increase parasitic capacitances and/or inductances between the common-mode filter 108 and the decoupling network 110, undesirably shifting the resonant frequency range of the common-mode filter 108. In some cases, an undesired shift in the resonant frequency range of the common-mode filter 108 may increase the common-mode noises 139 and 140.

In the depicted embodiment, the common-mode filter 108 is disposed away from (e.g., not directly coupled to) the decoupling network 110, and instead, is coupled directly to (e.g., coupled in-between) the first cell 120 and the second cell 122. As such, the parasitic capacitances and/or inductances of the common-mode filter 108 may have reduced dependency on the decoupling network 110. Moreover, the parasitic capacitances and/or inductances of the decoupling network 110 may have reduced dependency on the common-mode filter 108. As such, one or more values of the parasitic capacitances and/or inductances of the common-mode filter 108, the decoupling network 110, and/or between the common-mode filter 108 and the decoupling network 110 may be reduced. Moreover, the resonant frequency of the common-mode filter 108 may not undesirably shift or may have a reduced undesirable shift, for example, compared to other VCOs having the common-mode filter 108 directly coupled to the decoupling network 110. Accordingly, the VCO 66 may have an increased and/or expanded oscillation frequency bandwidth based on the reduced the common-mode noises 139 and 140.

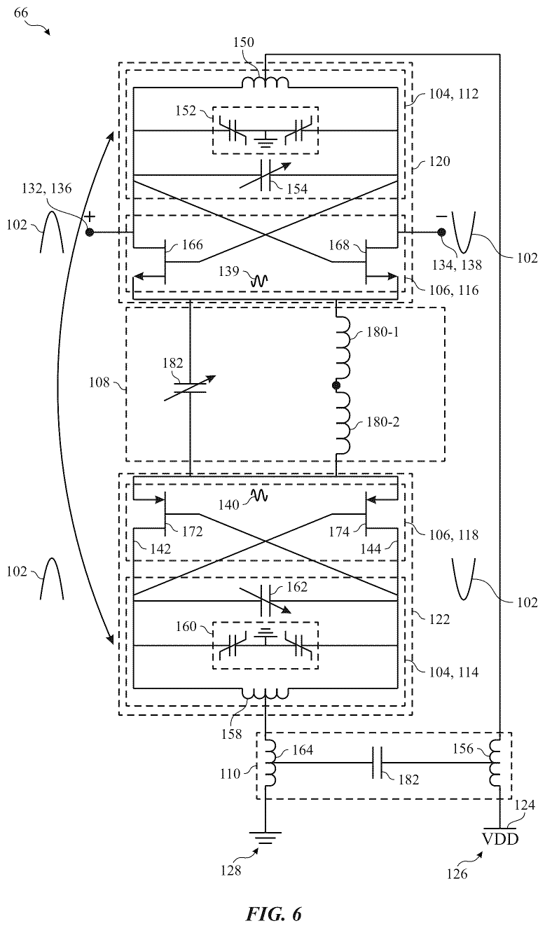

FIG. 6 is a schematic diagram of the VCO 66 including a differential capacitor and a differential inductor with the common-mode filter 108, according to embodiments of the present disclosure. In the depicted embodiment, the first LC tank 112 may include a first inductor 150, a first capacitor bank 152, and a first variable capacitor 154 (e.g., a varactor). Moreover, the second LC tank 114 may include a second inductor 158, a second capacitor bank 160, and a second variable capacitor 162 (e.g., a varactor). Additionally or alternatively, the first LC tank 112 and/or the second LC tank 114 may include switched capacitor circuitry, among other possibilities. The first capacitor bank 152 and the second capacitor bank 160 may each include a number of capacitors.

The first inductor 150 may be coupled to the power source terminal 124 via a first decoupling inductor 156 (e.g., a first degeneration inductor) of the decoupling network 110. The first decoupling inductor 156 may reduce noise of the voltage terminal 124 at the VCO 66 and/or reduce noise of the VCO 66 at the voltage terminal 124. The first decoupling inductor 156 may be tapped onto (e.g., coupled to a winding of) the first inductor 150. For example, the first decoupling inductor 156 may be tapped onto a center tap of the first inductor 150 dividing the first inductor 150 to two split (e.g., halved) inductors. Alternatively or additionally, the first decoupling inductor 156 may be tapped onto any other part or portion of the first inductor 150, among other possibilities.

The second inductor 158 may be coupled to the ground terminal 128 via a second decoupling inductor 164 (e.g., a second degeneration inductor) of the decoupling network 110. The second decoupling inductor 164 may reduce noise of the ground terminal 128 at the VCO 66 and/or reduce noise of the VCO 66 at the ground terminal 128. The second decoupling inductor 164 may be tapped onto a winding of the second inductor 158. For example, the second decoupling inductor 164 may be tapped onto a center tap of the second inductor 158, among other possibilities. In some embodiments, the decoupling network 110 may include a decoupling capacitor 182 coupled to the first decoupling inductor 156 and the second decoupling inductor 164. For example, the decoupling capacitor 182 may be tapped onto (e.g., to a center tap of) a winding of the first decoupling inductor 156 and tapped onto a winding of the second decoupling inductor 164.

The first inductor 150 and the second inductor 158 may inductively couple with a coupling factor (K) equal to or greater than a first threshold for signals having an oscillation frequency within the resonant frequency range of the LC tank circuitry 104. The first threshold may be 0.3 or less or greater, 0.4 or greater, 0.44 or greater, 0.5 or greater, 0.72 or greater, 0.76 or greater, 0.9 or greater, or 1, among other possibilities. In different embodiments, the first inductor 150 and the second inductor 158 may have different dimensions corresponding to the resonant frequency range of the LC tank circuitry 104. For example, the first inductor 150 may inductively couple to the second inductor 158 forming a transformer to generate or provide the output signal 102 having an oscillation frequency within the resonant frequency range of the LC tank circuitry 104.

Moreover, the first inductor 150 and the second inductor 158 may inductively uncouple for signals having an oscillation frequency outside the resonant frequency range of the LC tank circuitry 104 based on a coupling factor equal to or less than a second threshold. The second threshold may be 1 or less, 0.9 or less, 0.85 or less, 0.72 or less, 0.64 or less, 0.5 or less, 0.4 or less, 0.2 or less, 0.1 or less, or 0.05 or less, among other possibilities. As such, the first inductor 150 and the second inductor 158 may inductively uncouple for the common-mode noises 139 and 140 having the undesired oscillation frequency outside the resonant frequency range of the LC tank circuitry 104. Accordingly, the first inductor 150 and the second inductor 158 may at least partly uncouple and/or isolate the first cell 120 from the second cell 122 for the common-mode noises 139 and 140.

In some cases, a capacitance value and an inductance value of the first LC tank 112 and the second LC tank 114 may be equal, nearly equal, or substantially equal. It should be appreciated that in different embodiments, the first LC tank 112 and the second LC tank 114 may include different circuit components. For example, the first LC tank 112 and the second LC tank 114 may include a different number of capacitors and/or inductors to generate the output signal 102. The capacitance value and the inductance value of the first LC tank 112 and the second LC tank 114 may correspond to the oscillation frequency of the output signal 102. In some cases, the oscillation frequency may be above a threshold (e.g., above 0.1 GHz, above 1 GHz, above 10 GHz, above 19 GHz, and so on) and/or within the resonant frequency range of the LC tank circuitry 104 (e.g., 24.25-300 GHz or mmWave frequencies, among other possibilities).

In the depicted embodiment, the first current source 116 may include a first N-channel switch 166 (e.g., a first n-channel metal-oxide semiconductor (NMOS) switch) and a second N-channel switch 168 (e.g., a second NMOS switch) forming a first voltage-controlled current source. Moreover, the second current source 118 may include a first P-channel switch 172 (e.g., a first p-channel metal-oxide semiconductor (PMOS) switch) and a second P-channel switch 174 (e.g., a second PMOS switch) forming a second voltage-controlled current source. It should be appreciated that in alternative or additional embodiments, the first current source 116 and/or the second current source 118 may each include different switches, such as any viable transistor, and/or a different number of switches to provide the voltage-controlled current source.

A gate terminal of the second N-channel switch 168 may be coupled (e.g., cross-coupled) to a drain terminal of the first N-channel switch 166 via the first node 132. A gate terminal of the first N-channel switch 166 may be coupled (e.g., cross-coupled) to a drain terminal of the second N-channel switch 168 via the second node 134. As mentioned above, in some embodiments, the first node 132 may correspond to the positive output terminal 136 and the second node 134 may correspond to the negative output terminal 138 of the VCO 66. The first inductor 150, first capacitor bank 152, and first variable capacitor 154 may be coupled to the drain terminal of the first N-channel switch 166 via the first node 132 and may be coupled to the drain terminal of the second N-channel switch 168 via the second node 134.

The drain terminals of the first N-channel switch 166 and the second N-channel switch 168 may be coupled to the voltage terminal 124 via the first LC tank 112 and the decoupling network 110. In particular, the drain terminals of the first N-channel switch 166 and the second N-channel switch 168 may be coupled to the voltage terminal 124 via the first inductor 150 and the first decoupling inductor 156 of the decoupling network 110.

A gate terminal of the second P-channel switch 174 may be coupled (e.g., cross-coupled) to a drain terminal of the first P-channel switch 172 via the third node 142. A gate terminal of the first P-channel switch 172 may be coupled (e.g., cross-coupled) to a drain terminal of the second P-channel switch 174 via the fourth node 144. As mentioned above, in some embodiments, the third node 142 and the fourth node 144 may correspond to or have a second positive output terminal and a second negative output terminal of the VCO 66 (e.g., in lieu or in addition to the positive output terminal 136 and the negative output terminal 138). The second inductor 158, second capacitor bank 160, and second variable capacitor 162 may be coupled to the drain terminal of the first P-channel switch 172 via the third node 142 and may be coupled to the drain terminal of the second P-channel switch 174 via the fourth node 144.

The drain terminals of the first P-channel switch 172 and the second P-channel switch 174 may be coupled to the ground terminal 128 via the second LC tank 114 and the decoupling network 110. In particular, the drain terminals of the first P-channel switch 172 and the second P-channel switch 174 may be coupled to the ground terminal 128 via the second inductor 158 and the second decoupling inductor 164.

The source terminals of the first N-channel switch 166, the second N-channel switch 168, the first P-channel switch 172, and the second P-channel switch 174 may be coupled to the common-mode filter 108. For example, the common-mode filter 108 may couple the source terminals of the first N-channel switch 166 and the second N-channel switch 168 to the source terminals of the first P-channel switch 172 and the second P-channel switch 174. As mentioned above, the common-mode filter 108 may conduct the bias voltage 126, the DC signal (e.g., the electrical currents), and/or the output signal 102 (e.g., the differential output signal) between the first cell 120 and the second cell 122. As such, the first current source 116 and the second current source 118 may generate the DC signal based on the bias voltage 126. Moreover, the first inductor 150 and the second inductor 158 may differentially receive the DC signal in response to the VCO 66 receiving the bias voltage 126 (or any other viable input signal). Furthermore, the first LC tank 112 and the second LC tank 114 may generate the output signal 102.

In the depicted embodiment, the common-mode filter 108 may include a differential inductor 180 and a differential capacitor 182. First terminals of the differential inductor 180 and the differential capacitor 182 may be coupled to the source terminals of the first N-channel switch 166 and the second N-channel switch 168. Second terminals of the differential inductor 180 and the differential capacitor 182 may be coupled to the source terminals of the first P-channel switch 172 and the second P-channel switch 174. In some embodiments, the differential inductor 180 may include a single inductor (e.g., a single winding). In alternative or additional embodiments, the differential inductor 180 may include a first inductor 180-1 (e.g., a first winding) and a second inductor 180-2 (e.g., a second winding) serially coupled. For example, the first winding and the second winding may each correspond to half or any other viable portion of the windings of the differential inductor 180. Moreover, the first inductor 180-1 and the second inductor 180-2 may each have half or any other portion of the inductance of the differential inductor 180.

A capacitance value of the differential capacitor 182 and an inductance value of the differential inductor 180 may each correspond to the resonant frequency range of the common-mode filter 108. As such, the differential inductor 180 and the differential capacitor 182 may reduce (e.g., suppress) the undesired common-mode noises 139 and 140 of the output signal 102. The differential capacitor 182 and the differential inductor 180 may be disposed away from (e.g., not directly coupled to) the decoupling network 110, and instead, may be coupled directly to (e.g., coupled in-between) the first cell 120 and the second cell 122. As such, the parasitic capacitances and/or inductances of the differential capacitor 182 and the differential inductor 180 may have reduced dependency on the decoupling network 110. Moreover, one or more values and/or undesired variations of the parasitic capacitances and/or inductances of the differential capacitor 182 and the differential inductor 180 may be reduced. Accordingly, the source terminals of the first N-channel switch 166, the second N-channel switch 168, the first P-channel switch 172, and the second P-channel switch 174 may receive signals with reduced current fluctuations (e.g., noise current fluctuations). For example, the source terminals of the first N-channel switch 166, the second N-channel switch 168, the first P-channel switch 172, and the second P-channel switch 174 may receive signals with improved stability.

The VCO 66 may have an increased and/or expanded oscillation frequency bandwidth based on the reduced current fluctuations at the source terminals of the switches 166, 168, 172, and 174. Moreover, the VCO 66 may have reduced undesired voltage and/or the frequency offsets on the output signal 102. In some cases, the VCO 66 may have improved signal to noise ratio for generating the output signal 102 without increased power consumption. Alternatively or additionally, the VCO 66 may generate the output signal 102 with a phase noise (e.g., a constant phase noise, a reduced phase noise) by consuming a reduced amount of electrical power compared to other VCOs. That is, the VCO 66 may have improved efficiency for generating the output signal 102 with a phase noise. Accordingly, the VCO 66 may improve operations of the transmitter 52, the receiver 54, and/or the electronic device 10 based on generating signals with improved signal integrity based the reduced noise and/or improved efficiency based on the reduced power consumption. For example, the improved signals may reduce a timing error rate and/or improve integrity of transmission data and/or reception data, among other things.

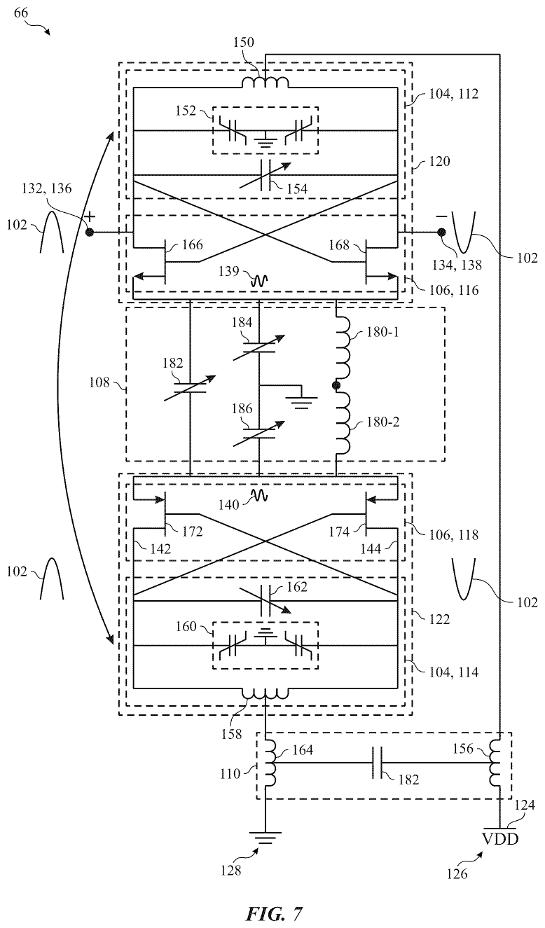

FIG. 7 is a schematic diagram of the VCO 66 including single-ended capacitors 184 and 186, the differential capacitor 182, and the differential inductor 180 with the common-mode filter 108, according to embodiments of the present disclosure. As mentioned above, the first terminals of the differential inductor 180 and the differential capacitor 182 may be coupled to the source terminals of the first N-channel switch 166 and the second N-channel switch 168. The second terminals of the differential inductor 180 and the differential capacitor 182 may be coupled to the source terminals of the first P-channel switch 172 and the second P-channel switch 174. Moreover, the differential inductor 180 may include a single winding. Alternatively, the differential inductor 180 may include the first differential inductor 180-1 and the second differential inductor 180-2.

In the depicted embodiment, a first terminal of the first single-ended capacitor 184 is coupled to the source terminals of the first N-channel switch 166 and the second N-channel switch 168. A first terminal of the second single-ended capacitor 186 is coupled to a second terminal of the first single-ended capacitor 184. Moreover, a ground terminal (e.g., the ground terminal 128) is coupled to the second terminal of the first single-ended capacitor 184 and the first terminal of the second single-ended capacitor 186. A second terminal of the second single-ended capacitor 186 is coupled to the source terminals of the first P-channel switch 172 and the second P-channel switch 174.

The single-ended capacitors 184 and 186 may have capacitance values to reduce (e.g., suppress) the undesired common-mode noises 139 and 140 and/or one or more harmonics of the output signal 102 at the source terminals of the first N-channel switch 166, the second N-channel switch 168, the first P-channel switch 172, and the second P-channel switch 174. Accordingly, the VCO 66 may have an increased and/or expanded noise reduction frequency bandwidth based on the reduced parasitic capacitance and/or inductance values at the source terminals of the switches 166, 168, 172, and 174.

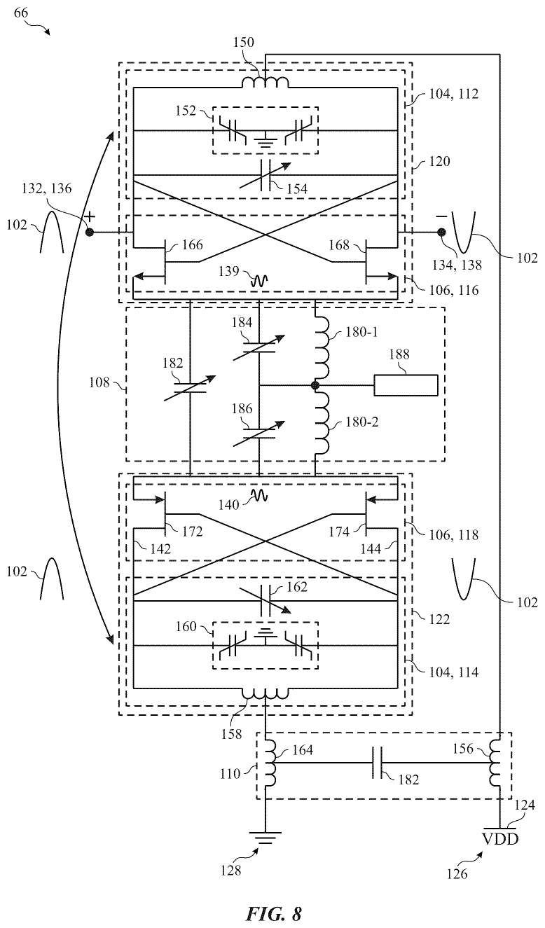

FIG. 8 is a schematic diagram of the VCO 66 including an impedance component 188, the single-ended capacitors 184 and 186, the differential capacitor 182, and the differential inductor 180 with the common-mode filter 108, according to embodiments of the present disclosure. As mentioned above, the first terminals of the differential inductor 180 and the differential capacitor 182 may be coupled to the source terminals of the first N-channel switch 166 and the second N-channel switch 168. The second terminals of the differential inductor 180 and the differential capacitor 182 may be coupled to the source terminals of the first P-channel switch 172 and the second P-channel switch 174. Moreover, the differential inductor 180 may include a single winding. Alternatively, the differential inductor 180 may include the first differential inductor 180-1 and the second differential inductor 180-2.

In the depicted embodiment, the impedance component 188 is tapped onto a winding of the differential inductor 180. For example, the impedance component 188 may be coupled to any part of the winding of the differential inductor 180, such as a center tap of the winding of the differential inductor 180. In some embodiments, the impedance component 188 may be coupled to between the first differential inductor 180-1 and the second differential inductor 180-2. Moreover, the impedance component 188 is coupled to the second terminal of the first single-ended capacitor 184 and the first terminal of the second single-ended capacitor 186.

The impedance component 188 may include resistors, capacitors, inductors, or any combination thereof, among other possibilities. The impedance component 188 may have an impedance value to reduce (e.g., suppress) the undesired common-mode noises 139 and 140 and/or one or more harmonics of the output signal 102 at the source terminals of the first N-channel switch 166, the second N-channel switch 168, the first P-channel switch 172, and the second P-channel switch 174. Accordingly, the VCO 66 may have an increased and/or expanded noise reduction frequency bandwidth based on the reduced parasitic capacitance, parasitic inductance values, and/or current fluctuations at the source terminals of the switches 166, 168, 172, and 174.

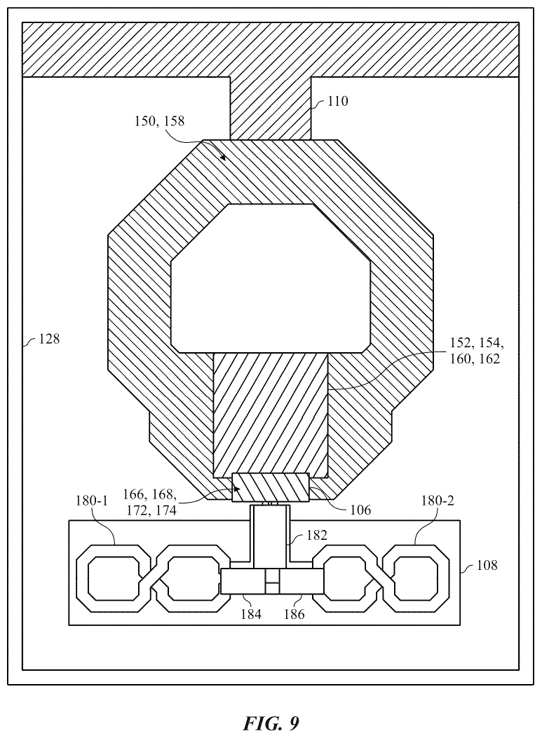

FIG. 9 is a layout of the VCO 66, according to embodiments of the present disclosure. In the depicted embodiment, the LC tank circuitry 104, the current source circuitry 106, the common-mode filter 108, the decoupling network 110, and the ground terminal 128 are shown. The LC tank circuitry 104 may include the inductors 150 and 158, the capacitor banks 152 and 160, the variable capacitors 154 and 162. The current source circuitry 106 may include the switches 166, 168, 172, and 174. The common-mode filter 108 may include the differential inductor 180 (e.g., the differential inductors 180-1 and 180-2), the differential capacitor 182, and the single-ended capacitors 184 and 186. In alternative or additional embodiments, the common-mode filter 108 may include the impedance component 188 discussed above.

The common-mode filter 108 is not directly coupled to the decoupling network 110. For example, the common-mode filter 108 is disposed away from the decoupling network 110 in the layout. As illustrated, the common-mode filter 108 is disposed at an opposite side or end of the VCO 66 when compared to the decoupling network 110, and instead, is coupled directly to (e.g., coupled in-between) the first inductor 150 of the first cell 120 and the second inductor 158 of the second cell 122. The VCO 66 may occupy a similar area compared to other VCOs having the decoupling network 110 coupled to the common-mode filter 108.

For example, the VCO 66 may not include additional circuitry (e.g., filters) to reduce (e.g., suppress) the undesired common-mode noises 139 and 140 and/or one or more harmonics of the output signal 102 at the source terminals of the switches 166, 168, 172, and 174. As such, the VCO 66 may be improved based on having reduced electrical current fluctuations while occupying the same (e.g., a similar) area compared to other VCOs. Accordingly, the VCO 66 may not occupy additional area based having the common-mode filter 108 disposed at the opposite side of the decoupling network 110 compared to other VCOs having a decoupling network coupled to a common-mode filter and/or is disposed at the same side of a common-mode filter. For example, the common-mode filter 108 may be disposed at a second side (e.g., second end) of the VCO 66 above the inductors 150 and 158 while the decoupling network 110 is disposed on a first side (e.g., first end) of the VCO 66 below the inductors 150 and 158.

Moreover, the first inductor 150 may be disposed within a threshold proximity of the second inductor 158. The threshold proximity may be 1 picometer or less, 100 nano meter (nm) or less, 57 nm or less, 8 nm or less, 674 millimeter (mm) or less, 94 mm or less, 10 mm or less, 0.1 mm or less, among other possibilities. In some embodiments, the second inductor 158 may be overlaid on or under the first inductor 150, for example, on or into a printed circuit board (PCB), among other possibilities. As such, the first inductor 150 and the second inductor may occupy less surface area compared to an area occupied by the first inductor 150 and the second inductor 158 being disposed with a different disposition (e.g., side-by-side). In some cases, the first inductor 150 and the second inductor 158 may occupy an area corresponding to an area of either of the first inductor 150 or the second inductor 158 that is less than the area occupied by the first inductor 150 and the second inductor 158 disposed with a different disposition. For example, the first inductor 150 and the second inductor 158 may occupy an area corresponding to a portion of the area occupied by the first inductor 150 and the second inductor 158 being disposed side-by-side. With the foregoing in mind, it should be appreciated that the layout of FIG. 9 is provided as an example and the VCO 66 may have any other viable layout and/or variations of the layout.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

1. A voltage-controlled oscillator comprising:
a first inductor-capacitor tank circuit;
a first current source circuit coupled to the first inductor-capacitor tank circuit;
a differential capacitor having a first terminal coupled in series to the first current source circuit;
a differential inductor having a first terminal coupled in series to the first current source circuit;
a second current source circuit coupled in series to a second terminal of the differential capacitor and coupled in series to a second terminal of the differential inductor;
a second inductor-capacitor tank circuit coupled to the second current source circuit.

2. The voltage-controlled oscillator of claim 1, wherein the first current source circuit comprises a first N-channel switch and a second N-channel switch.

3. The voltage-controlled oscillator of claim 2, wherein the first terminal of the differential capacitor is coupled to a source terminal of the first N-channel switch and a source terminal of the second N-channel switch, and the first terminal of the differential inductor is coupled to the source terminal of the first N-channel switch and the source terminal of the second N-channel switch.

4. The voltage-controlled oscillator of claim 1, wherein the second current source circuit comprises a first P-channel switch and a second P-channel switch.

5. The voltage-controlled oscillator of claim 4, wherein a source terminal of the first P-channel switch is coupled to the second terminal of the differential capacitor and the second terminal of the differential inductor, and a source terminal of the second P-channel switch is coupled to the second terminal of the differential capacitor and the second terminal of the differential inductor.

6. The voltage-controlled oscillator of claim 1, comprising:
a first single-ended capacitor having a first terminal coupled to the first current source circuit; and
a second single-ended capacitor having
a first terminal coupled to a second terminal of the first single-ended capacitor, and
a second terminal coupled to the second current source circuit.

7. The voltage-controlled oscillator of claim 6, comprising an impedance component coupled to a center tap of the differential inductor, the second terminal of the first single-ended capacitor, and the first terminal of the second single-ended capacitor.

8. The voltage-controlled oscillator of claim 1, comprising:
a first decoupling inductor having
a first terminal coupled to a power source, and
a second terminal coupled to the first inductor-capacitor tank circuit; and
a second decoupling inductor having
a first terminal coupled to the second inductor-capacitor tank circuit, and
a second terminal coupled to a ground terminal.

9. The voltage-controlled oscillator of claim 1, wherein the voltage-controlled oscillator comprises differential output terminals coupled to the first inductor-capacitor tank circuit and the first current source circuit or coupled to the second inductor-capacitor tank circuit and the second current source circuit.

10. A transceiver comprising:
a voltage-controlled oscillator comprising:
a first current source circuit;
a differential capacitor having a first terminal coupled in series to the first current source circuit;
a differential inductor having a first terminal coupled in series to the first current source circuit;
a second current source circuit coupled in series to a second terminal of the differential capacitor and coupled in series to a second terminal of the differential inductor, wherein the voltage-controlled oscillator is configured to generate an output signal; and
a mixer coupled to the voltage-controlled oscillator, the mixer configured to generate a signal based on the output signal.

11. The transceiver of claim 10, wherein the voltage-controlled oscillator comprises
a first decoupling inductor having a first terminal coupled to a power source terminal,
a first inductor-capacitor tank circuit coupled to a second terminal of the first decoupling inductor, the first current source circuit coupled to the first inductor-capacitor tank circuit,
a second inductor-capacitor tank circuit coupled to the second current source circuit, and
a second decoupling inductor coupled to the second inductor-capacitor tank circuit and a ground terminal.

12. The transceiver of claim 10, wherein the differential capacitor and the differential inductor are configured to reduce a voltage amplitude of a common-mode noise signal or a second harmonic signal of the output signal of the voltage-controlled oscillator.

13. The transceiver of claim 10, wherein the first current source circuit comprises a first N-channel switch and a second N-channel switch, the first terminal of the differential capacitor being coupled to source terminals of the first N-channel switch and the second N-channel switch, and the first terminal of the differential inductor being coupled to source terminals of the first N-channel switch and the second N-channel switch.

14. The transceiver of claim 10, wherein the second current source circuit comprises a first P-channel switch and a second P-channel switch, source terminals of the first P-channel switch and the second P-channel switch being coupled to the second terminal of the differential capacitor and the second terminal of the differential inductor.

15. A voltage-controlled oscillator comprising:
a first current source circuit;
a differential capacitor having a first terminal directly coupled in series to the first current source circuit;
a differential inductor having a first terminal directly coupled in series to the first current source circuit; and
a second current source circuit directly coupled in series to a second terminal of the differential capacitor and coupled in series to a second terminal of the differential inductor.

16. The voltage-controlled oscillator of claim 15, wherein the first current source circuit comprises a first N-channel switch and a second N-channel switch.

17. The voltage-controlled oscillator of claim 16, wherein the first terminal of the differential capacitor is coupled to a source terminal of the first N-channel switch and a source terminal of the second N-channel switch, and the first terminal of the differential inductor is coupled to the source terminal of the first N-channel switch and the source terminal of the second N-channel switch.

18. The voltage-controlled oscillator of claim 15, wherein the second current source circuit comprises a first P-channel switch and a second P-channel switch.

19. The voltage-controlled oscillator of claim 18, wherein a source terminal of the first P-channel switch is coupled to the second terminal of the differential capacitor and the second terminal of the differential inductor, and a source terminal of the second P-channel switch is coupled to the second terminal of the differential capacitor and the second terminal of the differential inductor.

20. The voltage-controlled oscillator of claim 15, comprising a decoupling network disposed on a first end of a layout, wherein the differential capacitor and the differential inductor are disposed on a second end of the layout different from the first end.
